(19) United States
(12) Patent Application Publication
(10) Pub. No.: US 2007/0228403 A1
(43) Pub. Date: Oct. 4, 2007

(54) Micro-element package module and manufacturing method thereof

(75) Inventors: Min Seog Choi, Seoul (KR); Seung Wan Lee, Suwon-si (KR); Woon Bae Kim, Suwon-si (KR); Kyu Dong Jung, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/585,260

(22) Filed: Oct. 24, 2006

(30) Foreign Application Priority Data
Apr. 3, 2006 (KR) 10-2006-0030274

(51) Int. Cl. H01L 33/00

(52) U.S. Cl. 257/98

(57) ABSTRACT

A micro-element package module which can reduce manufacturing costs and can be advantageous for mass production due to simplifying its structure and manufacturing process, and also can facilitate miniaturization and promote thinness, and a method of manufacturing the micro-element package module. The micro-element package module includes: an element substrate having a micro-element on a top surface of the element substrate; a circuit substrate that is provided around the element substrate; and an element housing that is provided above the element substrate and the circuit substrate, and includes a connecting section for electrically connecting the micro-element and the circuit substrate.

### CROSS-REFERENCE TO RELATED APPLICATION

This application claims priority from Korean Patent Application No. 10-2006-0030274, filed on Apr. 3, 2006, in the Korean Intellectual Property Office, the disclosure of which is incorporated herein by reference.

### BACKGROUND OF THE INVENTION

1. Field of the Invention

Apparatuses and methods consistent with the present invention relates to a micro-element package and a method of manufacturing the micro-element package, and more particularly, to a micro-element package module which can reduce manufacturing costs, can be advantageous for mass production due to simplifying its structure and manufacturing process, and also can facilitate miniaturization and promote thinness, and a method of manufacturing the micro-element package.

2. Description of Related Art

An image sensor is a device which changes light into an electrical signal and utilized in various fields of our daily lives.

The image sensor includes a light receiving portion which generates charges in accordance with received light and a circuit portion which converts the charges into a voltage and processes the converted voltage into a final form. According to a driving method, the image sensor may be divided into a charge coupled device (CCD) image sensor and a complementary metal oxide semiconductor (CMOS) image sensor.

Due to an electronics package technology, the image sensor is manufactured as an image sensor module in an image sensor chip and installed in various types of products. In this instance, a CMOS image sensor module is manufactured by utilizing a Chip On Board (COB) method, a Chip On Film (COF) method, etc., so that the size and height of the CMOS image sensor module may be reduced according to a recent tendency of light, thin, and miniaturized image sensor modules.

FIG. 1 is a cross-sectional diagram illustrating a structure of an image sensor module according to a related art.

As shown in FIG. 1, the COB method is a method of attaching a printed circuit board (PCB) 10 on a rear surface of the image sensor chip 20 by using a die bonding agent and connecting an electrode of the PCB 10 and an input/output (I/O) terminal of the image sensor chip 20, which can be advantageous for mass production by utilizing a process similar to an existing semiconductor production line.

However, the method as described above must include a space for wire bonding. Accordingly, the image sensor module is enlarged. Accordingly, in the method as described above, the height of the image sensor module may not be reduced by more than a predetermined value. Also, the method may not be applicable to a device which is manufactured thin and in a small size.

Also, the image sensor module according to the above-described method must be individually packaged in a chip unit. Accordingly, productivity may be deteriorated and manufacturing costs may be increased. Also, in the case of the image sensor module constructed as above, a yield may be deteriorated due to contamination by particles during a manufacturing process.

### SUMMARY OF THE INVENTION

The present invention provides a micro-element package module which can reduce a size of a package module by reducing a bonding area, and also can form a thin module using a wafer-level-package (WLP) process, and a method of manufacturing the micro-element package module.

The present invention also provides a micro-element package module which can physically fix an element substrate formed with a micro-element and a circuit substrate for an external connection, and thereby, can electrically connect the micro-element substrate and the circuit substrate through a process of directly installing an element housing to the element substrate, and a method of manufacturing the micro-element package module.

The present invention also provides a micro-element package module which can indirectly connect an element substrate formed with a micro-element and a circuit substrate via an element housing, and thereby, can prevent a vibration and an impact of the circuit substrate from being directly transferred to the element substrate, and a method of manufacturing the micro-element package module.

The present invention also provides a micro-element package module which can reduce manufacturing costs and can be advantageous for mass production due to simplifying its structure and manufacturing process, and a method of manufacturing the micro-element package module.

The present invention also provides a micro-element package module which can be easily and quickly manufactured to be advantageous for mass production and also can prevent a yield from decreasing due to contamination by particles and the like, and a method of manufacturing the micro-element package module.

The present invention also provides a micro-element package module which can be manufactured thin and in a small size, and a method of manufacturing the micro-element package module.

According to an aspect of the present invention, there is provided a micro-element package module including: an element substrate having a micro-element on a top surface of the element substrate; a circuit substrate that is provided around the element substrate; and an element housing that is provided above the element substrate and the circuit substrate, and includes a connecting section for electrically connecting the micro-element and the circuit substrate.

A related art utilizes an electrical connection method such as a wire bonding. Also, since the electrical connection and a housing installation are separately performed, a size of a package module may not be reduced and a manufacturing process becomes complicated. However, the micro-element package module according to the present invention may make a physical connection at a wafer level of an element substrate and a circuit substrate, e.g. a printed circuit board (PCB) and a flexible printed circuit board (FPCB), via an element housing. Also, the micro-element package module may electrically connect the micro-element and the circuit substrate via the connecting section which is formed on the element housing.

Also, while maintaining the package module to be thin and in a small size, the element substrate is positioned in an inner location of the circuit substrate, which prevents the element substrate from being exposed to an external hazard. Also, since the element substrate and the circuit substrate are indirectly connected to each other via the element housing, it is possible to prevent the element substrate from being damaged by an external impact, such as an excessive vibration and direct impact.

A metal pad is formed in a minute pattern on a bottom surface of the element housing, so as to electrically connect terminals of the circuit substrate and the element substrate. In this instance, the element substrate and the circuit substrate may be electrically connected to each other via various methods, such as a method of ultrasonic bonding, a method of using metal or polymer adhesives, and the like.

### BRIEF DESCRIPTION OF THE DRAWINGS

The above and/or other aspects of the present invention will become apparent and more readily appreciated from the following detailed description of exemplary embodiments, taken in conjunction with the accompanying drawings, in which:

FIG. 1 is a cross-sectional view illustrating a structure of an image sensor module according to a related art;

FIG. 2 is a cross-sectional view illustrating a structure of a micro-element package module according to an exemplary embodiment of the present invention;

FIG. 3 is a partially enlarged view of a connecting portion of elements shown in FIG. 2;

FIG. 4 is a top view illustrating a structure of a micro-element package module according to an exemplary embodiment of the present invention;

FIG. 5 is a cross-sectional view illustrating a structure of a micro-element package module according to an exemplary embodiment of the present invention;

FIG. 6 is a cross-sectional view illustrating a structure of a micro-element package module according to an exemplary embodiment of the present invention;

FIG. 7 is a cross-sectional view illustrating a structure of a micro-element package module according to another exemplary embodiment of the present invention;

FIG. 8 is a cross-sectional view illustrating a structure of a micro-element package module according to yet another exemplary embodiment of the present invention; and

FIGS. 9 through 11 are cross-sectional views illustrating a method of manufacturing a micro-element package module according to an exemplary embodiment of the present invention.

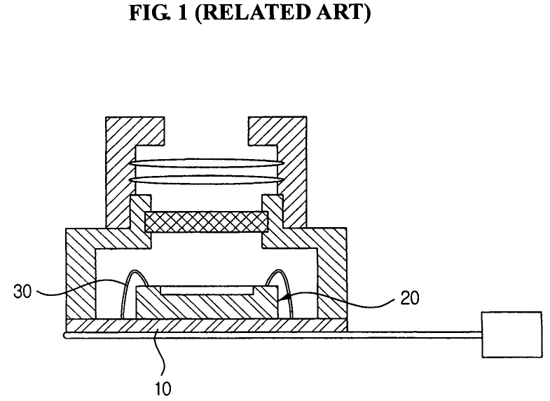

### DETAILED DESCRIPTION OF EXEMPLARY EMBODIMENTS

Reference will now be made in detail to exemplary embodiments of the present invention, examples of which are illustrated in the accompanying drawings, wherein like reference numerals refer to the like elements throughout. The exemplary embodiments are described below in order to explain the present invention by referring to the figures.

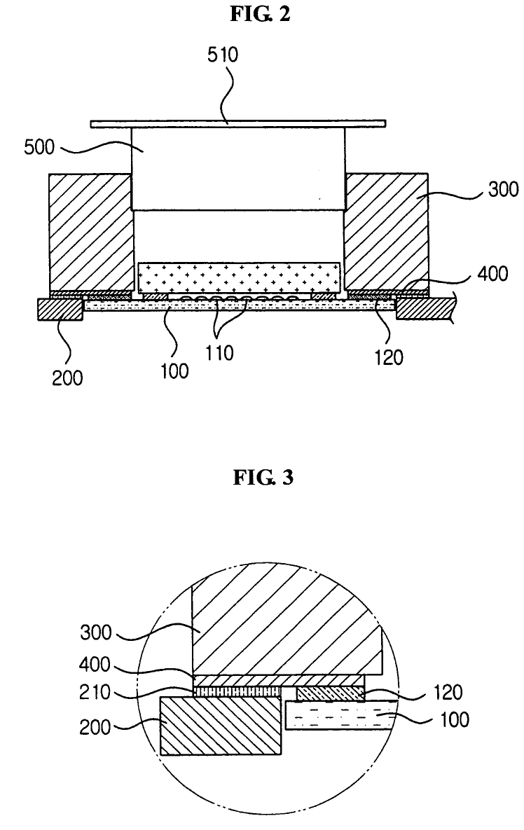

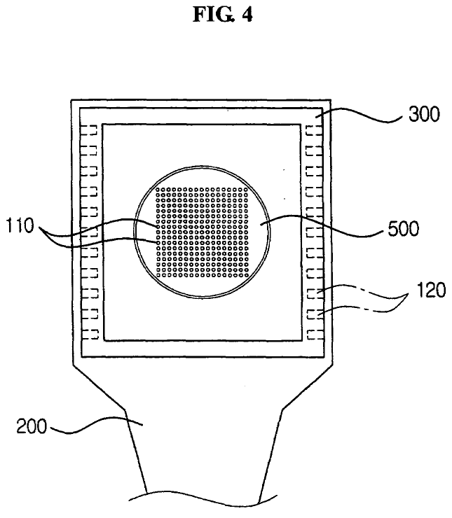

FIG. 2 is a cross-sectional view illustrating a structure of a micro-element package module according to an exemplary embodiment of the present invention, FIG. 3 is a partially enlarged view of a connecting portion of elements shown in FIG. 2, and FIG. 4 is a top view illustrating a structure of a micro-element package module according to an exemplary embodiment of the present invention.

As shown in FIGS. 2 through 4, the micro-element package module according to the exemplary embodiment of the present invention includes: an element substrate 100 having a micro-element 110 on a top surface of the element substrate 100; a circuit substrate 200 that is provided around the element substrate 100; and an element housing 300 that is provided above the element substrate 100 and the circuit substrate 200, and includes a connecting section for electrically connecting the micro-element 110 and the circuit substrate 200.

The element substrate 100 is provided by a wafer made of silicon, in this case, the wafers may be provided in various sizes, such as four inches, six inches, eight inches, ten inches, and the like. In the present embodiment, an example that the element substrate 100 is provided by the wafer made of silicon is taken, but depending upon circumstances, an element substrate may be provided by a wafer made of lithium-niobate (LiNbO3), lithium tantalite (LiTaO3), quartz, and the like.

An opto-electronics element such as an image sensor may be utilized for the micro-element 110. Also, in addition to the image sensor for obtaining an image, a micromechanical engineering element, a microelectronics element, and an opto-electronics element which can react with a light or other elements may be utilized for the micro-element 110. Hereinafter, an example of utilizing the image sensor for the micro-element 110 will be described.

The micro element 110 is formed on a center portion of the top surface of the element substrate 100. A plurality of electrode pads 120 are provided around the micro-element 110 to be electrically connected to the micro-element 110 in a certain pattern. The plurality of electrode pads 120 may be manufactured together with the micro-element 110. In this instance, the electrode pad 120 forms a structure which is electrically connected to the micro-element 110, and may provide an input/output (I/O) terminal of the micro-element 110.

The circuit substrate 200 may be electrically connected to the micro-element 110 via the connecting section of the element housing 300 which is adjacently provided around the element substrate 100. A flexible PCB or a rigid PCB may be utilized for the circuit substrate 200.

The element housing 300 is provided above the element substrate 100 and the circuit substrate 200. Also, the element housing 300 is formed above the electrode pad 120 to cover a top surface of the electrode pad 120.

The element housing 300 may have a transparent or translucent portion so that the micro-element 110 may be optically exposed through the transparent or translucent portion. Namely, the element housing 300 may be formed in a hollow cylinder which has a circular or a polygonal section, so that the micro-element 110 may be exposed when the element housing 300 is disposed above the element substrate 100. In this instance, the element housing 300 may include a lens portion 500 which is provided above the micro-element 110. Also, a lens cover 510 may be provided on the lens portion 500. Depending upon circumstances, a functional filter, such as an infrared filter may be installed to the element housing 300 so as to be disposed above the micro-element 110.

The element housing 300 includes the connecting section for electrically connecting the micro-element 110 of the element substrate 100 and the circuit substrate 200. In this instance, an end of the connecting section may be electrically connected to the electrode pad 120 and another end of the connecting section may be electrically connected to the circuit substrate 200.

The connecting section includes a metal pad 400 which is formed on a bottom surface of the element housing 300. The metal pad 400 may be formed in a minute pattern which connects each individual electrode pad in the plurality of electrode pads 120 to a single connection terminal 210 of the circuit substrate 200. The connecting section is for making a surface contact with the electrode pad 120 and the connection terminal 210, and also electrically connecting both the electrode pad 120 and the connection terminal 210, utilizing various connecting methods. As an example, the electrode pad 120 and the connection terminal 210 may be electrically connected to each other by forming a via hole in the element housing 300 or a forming a detour path.

Referring again to FIGS. 2 through 4, the metal pad 400 is formed on the bottom surface of the element housing 300 by electroplating, plating, and the like. Accordingly, when the element housing 300 is disposed above the element substrate 100 and the circuit substrate 200, an end of the metal pad 400 is electrically connected to the electrode pad 120 and another end of the metal pad 400 is electrically connected to the connection terminal 210 whereby the micro-element 110 and the circuit substrate 200 may be electrically connected to each other. In this instance, the metal pad 400 may be integrally connected to the electrode pad 120 and the connection terminal 210 by an ultrasonic process.

As described above, according to an exemplary embodiment of the present invention, the circuit substrate 200 is provided around the element substrate 100, and the element housing 300 which is provided with the metal pad 400 on its bottom surface is disposed above the element substrate 100 and the circuit substrate 200, and the micro-element 110 and the circuit substrate 200 may be electrically connected to each other via the metal pad 400. Accordingly, a thickness of the package module may be reduced, and a light, thin and miniaturized module may be manufactured.

In particular, the structure described above enables the circuit substrate 200 to be provided around the element substrate 100, and not making contact with the element substrate 100. The module may thereby be manufactured thinner.

As described above, according to the exemplary embodiment of the present invention, when installing the element housing 300, the micro-element 110 and the circuit substrate 200 may be electrically connected to each other. Accordingly, the structure described above may simplify a manufacturing process of the module and also reduce manufacturing costs.

Also, as shown in FIG. 3, the bottom surface of the element substrate 100 is higher than, or positioned in an inner location of, the bottom surface of the circuit substrate 200. Namely, since the element substrate 100 is positioned in the inner location of the circuit substrate 200, the element substrate 100 may primarily be protected from an external enviornment, which is achieved by partially accommodating the element substrate 100 towards the element housing 300. Also, a contact height of the element substrate 100 and the element housing 300 may be adjusted when designing the module. In this case, the contact height may be determined regardless of a height of the circuit substrate 200.

The element substrate 100 and the circuit substrate 200 are indirectly connected to each other via the element housing 300. The circuit substrate 200 is connected to an external device, and positioned in an outer location of the element substrate 100. Accordingly, the circuit substrate 200 may be easily affected by an impact. Also, the impact may be transferred to the element substrate 100. However, since the element substrate 100 is indirectly connected to the circuit substrate 200 via the element housing 300, it is possible to prevent the impact from being directly transferred to the element substrate 100.

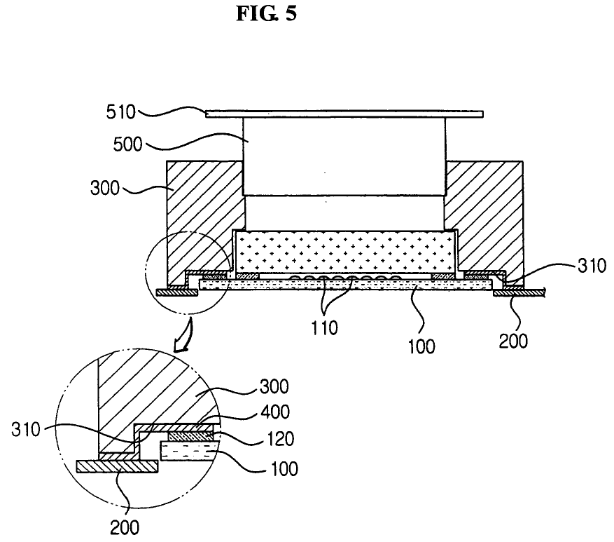

FIG. 5 is a cross-sectional view illustrating a structure of a micro-element package module according to an exemplary embodiment of the present invention.

As shown in FIG. 5, the element housing 300 may include a substrate receiving groove 310 so as to accommodate at least one portion of the element substrate 100. Namely, the substrate receiving groove 310 is formed in the bottom surface of the element housing 300 to a predetermined depth. With the at least one portion of the element substrate 100 being accommodated in the element housing 300 via the substrate receiving groove 310, the element substrate 100 may be provided below the element housing 300. In this instance, the bottom surface of the element substrate 100 may be positioned in an inner location of the circuit substrate 200.

The substrate receiving groove 310 is formed to have a depth corresponding to a thickness of the element substrate 100, so that the level of the bottom surface of the element substrate 100 is substantially identical to or higher than the level of the bottom surface of the circuit substrate 200. The structured described above may cover and distribute an impact via the element housing 300 when the impact is received by the module. Also, damage and performance deterioration caused by dropping and the like, may be prevented.

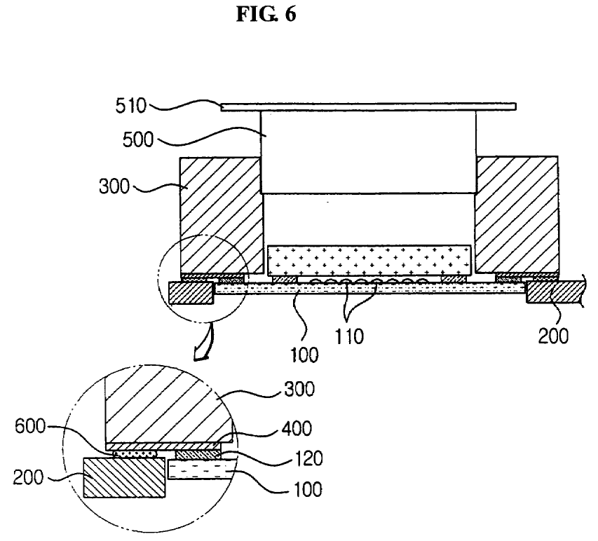

FIG. 6 is a cross-sectional view illustrating a structure of a micro-element package module according to an exemplary embodiment of the present invention.

As shown in FIG. 6, an electrical connection unit 600 may be further provided between the circuit substrate 200 and the metal pad 400 (a metal board), so as to electrically connect the circuit substrate 200 and the metal pad 400.

The electrical connection unit 600 may include at least one selected from a group consisting of a solder ball, a metal bump, and a conductive film, such as an anisotropic conductive film (ACF), and a conductive paste such as an anisotropic conductive paste (ACP).

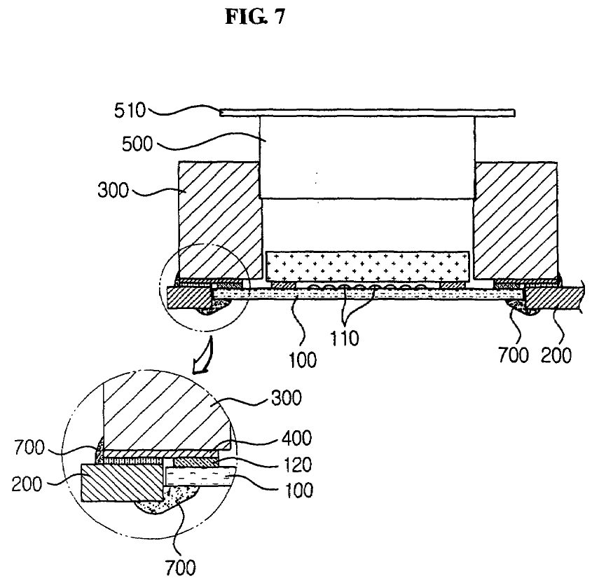

FIG. 7 is a cross-sectional view illustrating a structure of a micro-element package module according to another exemplary embodiment of the present invention.

As shown in FIG. 7, a sealing portion 700 may be formed on at least one of an area between the circuit substrate 200 and the element housing 300, and an area between the element substrate 100 and the circuit substrate 200. Hereinafter, an example that the sealing portions 700 are respectively formed between the circuit substrate 200 and the element housing 300 and between the element substrate 100 and the circuit substrate 200 will be described.

Specifically, since the sealing portions 700, made of polymer such as an epoxy, are formed between the circuit substrate 200 and the element housing 300, and between the element substrate 100 and the circuit substrate 200, the sealing portions 700 seal the inside of the housing and also absorb an impact which is caused by dropping and the like.

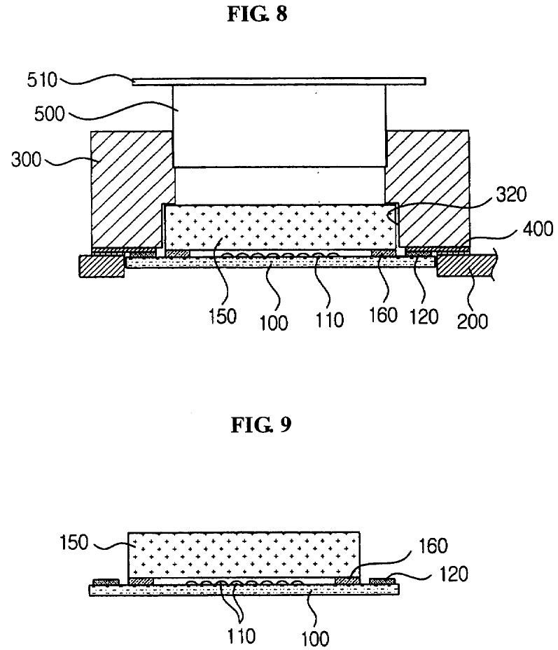

FIG. 8 is a cross-sectional view illustrating a structure of a micro-element package module according to yet another exemplary embodiment of the present invention.

As shown in FIG. 8, a transparent cover 150 is disposed above the element substrate 100, and a cover receiving groove 320 is formed in the element housing 300 to partially accommodate an outer portion of the transparent cover 150. The transparent cover 150 may be formed of a transparent or translucent material. As an example, the transparent cover 150 may be formed of a transparent glass. Depending upon exemplary embodiments, a functional coating layer, such as an antireflection coating layer and an infrared ray-proof coating layer, may be formed on the transparent cover 150.

Also, the transparent cover 150 is formed in a smaller size than the element substrate 100, so that the electrode pad 120 may be exposed on the top surface of the element substrate 100. The transparent cover 150 is disposed above the substrate 100 to be separated from the element substrate 100 by a predetermined distance so that a sealed air cavity may be formed above the micro-element 110. In this instance, the air cavity may be formed by a spacer 160 interposed between the element substrate 100 and the transparent cover 150.

Also, the spacer 160 may be formed by attaching a sealing pattern utilizing a thermal pressing and the like. In this instance, the sealing pattern is formed on at least one of the top surface of the element substrate 100 and the bottom surface of the transparent cover 150. Also, the sealing pattern may be formed of epoxy resin. The sealed air cavity may be formed between the element substrate 100 and the transparent cover 150 above the micro-element 110, by the spacer 160 that is formed by the sealing pattern.

The sealing pattern forms the spacer 160, and functions as a binding layer between the element substrate 100 and the transparent cover 150, and also functions as a sealing for forming the sealed air cavity. For this, the sealing pattern must have very strong adhesive and sealing properties. Accordingly, the sealing pattern may be attached by an appropriate heat and pressure, so that no opening and no gap may exist between the surfaces where the sealing pattern is attached, and the adhesiveness is preferably regular.

Also, when the transparent cover 150 is disposed above the micro-element 110, the cover receiving groove 320 may be formed in an inner wall portion of the element housing 300, so as to accommodate the fringe portion of the transparent cover 150. Through this, the transparent cover 150 may be stably combined and fixed.

Also, the structure described above may obtain the following effects.

Since the upper portion of the micro-element 110 is protected by the transparent cover 150, an element surface may not be contaminated by dust, and the like. Also, since the air cavity is formed between the micro-element 110 and the transparent cover 150, a focusing effect may not be deteriorated which is unlike the conventional structure filled with a transparent material. Accordingly, the present invention may be applicable to a high resolution image sensor in which the size of an image receiving device is small.

Hereinafter, a method of manufacturing a micro-element package module according to an exemplary embodiment of the present invention will be described.

FIGS. 9 through 11 are cross-sectional views illustrating a method of manufacturing a micro-element package module according to an exemplary embodiment of the present invention.

As shown in FIG. 9, the micro-element 110 and the electrode pad 120 are formed on the top surface of the element substrate 100. The transparent cover 150 is disposed above the micro-element 110. Also, the air cavity is formed between the micro-element 110 and the transparent cover 150. Due to the air cavity, the micro-element 110 may have an excellent optical performance.

As shown in FIG. 10, the connection terminal 210 is formed on the circuit substrate 200 and the circuit substrate 200 is provided adjacent to the element substrate 100. The circuit substrate 200 may be provided by a general PCB and utilized for fixing the package module to a device. Also, the circuit substrate 200 may be provided by an FPCB and utilized for connecting another device in the device. In this instance, a plurality of connection terminals 210 may be formed on the circuit substrate 200 so as to be electrically connected to the micro-element 110. The plurality of connection terminals 210 may be disposed in parallel around the corresponding electrode pad 120, namely around the element substrate 100, so as to be electrically connected to the electrode pad 120 of the element substrate 100.

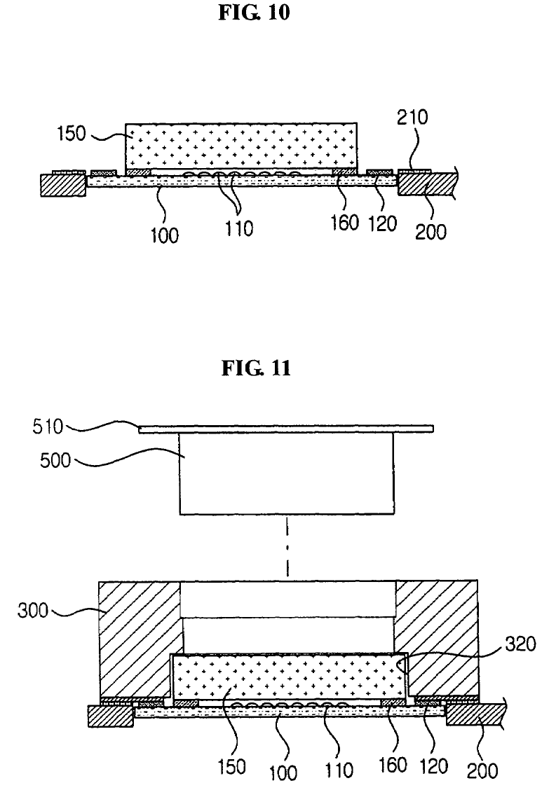

As shown in FIG. 11, the element substrate 100 and the circuit substrate 200 may be physically fixed via the element housing 300. Also, the electrode pad 120 and the connection terminal 210, shown in FIG. 10, of the circuit substrate 200 may be electrically connected to each other via the metal pad 400, shown in FIG. 8, which is formed on the bottom surface of the element housing 300. As described above, the metal pad 400 may be connected to the electrode pad 120 or the connection terminal 210 by an electrical connection method using at least one selected from a group consisting of a solder ball, a metal bump, and a conductive film, such as an anisotropic conductive film (ACF), and a conductive paste such as an anisotropic conductive paste (ACP). Also, the element housing 300 may utilize another binding unit so as to secure the connection between the element substrate 100 and the circuit substrate 200. The binding unit may include an adhesive material or an adhesive tape. Also, binding and sealing effects may be simultaneously obtained by applying epoxy and the like to the connecting section, as shown in FIG. 7.

Also, when installing the element housing 300, the bottom surface of the element substrate 100 is higher than the bottom surface of the circuit substrate 200. Accordingly, since the element substrate 100 is positioned in the inner location of the circuit substrate 200, the element substrate 100 may primarily be protected against an external impact. Also, since the element substrate 100 is connected to the circuit substrate 200 via the element housing 300, it is possible to prevent the external impact of the circuit substrate 200 from being directly transferred to the element substrate 100.

As described above, according to a micro-element package module and a method of manufacturing the micro-element package module of the exemplary embodiments of the present invention, the micro-element package module may be manufactured thinner and in a smaller size and can be advantageous for mass production due to simplifying its structure and have reduced manufacturing costs.

Also, according to an exemplary embodiment of the present invention, a package module may be manufactured in a small size by reducing a bonding area. Also, a module may be manufactured thin at a wafer-level-package (WLP) process.

Also, according to an exemplary embodiment of the present invention, an element substrate formed with a micro-element and a circuit substrate for an external connection may be physically fixed, and thereby, the micro-element and the circuit substrate may be electrically connected to each other through a process of directly installing an element housing to the element substrate.

Also, according to an exemplary embodiment of the present invention, it is possible to prevent a vibration and an impact of a circuit substrate from being directly transferred to an element substrate by indirectly connecting the element substrate formed with a micro-element and the circuit substrate via an element housing. Also, a location of the element substrate may be easily changed by adjusting a contact height of the element housing and the element substrate.

Also, according to an exemplary embodiment of the present invention, a circuit substrate may be provided around an element substrate, and not making contact with the element substrate. Also, a module may thereby be manufactured thinner.

Also, according to an exemplary embodiment of the present invention, a micro-element package may be manufactured at a wafer level package process. Accordingly, the micro-element package according an exemplary embodiment of to the present invention may be advantageous for mass production. Also, a product price may be decreased by reducing manufacturing costs.

Also, according to an exemplary embodiment of the present invention, a sealed air cavity may be formed above a micro-element. Accordingly, a contamination caused by particles may be prevented during a manufacturing process. Also, a decrease of a yield may be prevented.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A micro-element package module comprising:
an element substrate comprising a micro-element on a top surface of the element substrate;
a circuit substrate that is provided around the element substrate; and
an element housing that is provided above the element substrate and the circuit substrate, and comprises a connecting section for electrically connecting the micro-element and the circuit substrate.

2. The micro-element package module of claim 1, wherein an electrode is provided around the micro-element to be electrically connected to the micro-element.

3. The micro-element package module of claim 2, wherein the electrode pad is provided below the element housing to be electrically connected to the connecting section.

4. The micro-element package module of claim 2, wherein one end of the connecting section is electrically connected to the electrode pad and another end of the connecting section is electrically connected to the circuit substrate.

5. The micro-element package module of claim 4, wherein the connecting section includes a metal pad which is formed on a bottom surface of the element housing.

6. The micro-element package module of claim 1, comprising an electrical connection unit that is provided between the circuit substrate and the connecting section.

7. The micro-element package module of claim 6, wherein the electrical connection unit comprises at least one of a solder ball, a metal bump, a conductive film, and a conductive paste.

8. The micro-element package module of claim 1, wherein the element housing is formed with a substrate receiving groove so as to accommodate at least one portion of the element substrate.

9. The micro-element package module of claim 6, wherein a level a bottom surface of the element substrate is substantially identical to or higher than a level of a bottom surface of the circuit substrate.

10. The micro-element package module of claim 1, wherein a sealing portion is formed on at least one of an area between the element housing and the circuit substrate, and an area between the element substrate and the circuit substrate.

11. The micro-element package module of claim 1, further comprising a transparent cover that is disposed above the element substrate so as to cover the micro-element.

12. The micro-element package module of claim 11, wherein the transparent cover is disposed above the micro-element to be separated from the element substrate, so that an air cavity is provided between the micro-element and the transparent cover.

13. The micro-element package module of claim 1, wherein the element housing is formed such that the micro-element is optically exposed.

14. The micro-element package module of claim 13, wherein the element housing, which is in a shape of a hollow cylinder, is provided around the micro-element, and a lens portion is provided on an opening of the element housing.

15. The micro-element package module of claim 1, wherein the micro-element comprises at least one of a micromechanical engineering element, a microelectronics element, and an opto-electronics element.

16. A micro-element package module comprising:
an element substrate comprising a micro-element, a transparent cover that covers the micro-element, and an electrode pad that is provided around the transparent cover, electrically connected to the micro-element, and formed on a top surface of the element substrate;
a circuit substrate that is provided around the element substrate and comprises a connection terminal corresponding to the electrode pad; and
an element housing that physically connects the element substrate and the circuit substrate, and comprises a metal pad on a bottom surface of the element housing so as to electrically connect the electrode of the element substrate and the connection terminal of the circuit substrate.

17. The micro-element package module of claim 16, wherein the metal pad is connected to the electrode and the connection terminal via an electrical connection unit, and the electrical connection unit comprises at least one of a solder ball, a metal bump, a conductive film and a conductive paste.

18. The micro-element package module of claim 16, wherein a level of a bottom surface of the element substrate is substantially identical to or higher than a level of a bottom surface of the circuit substrate.

19. The micro-element package module of claim 16, wherein the micro-element comprises at least one of a micromechanical engineering element, a microelectronics element, and an opto-electronics element.

20. A method of manufacturing a micro-element package module, the method comprising:
providing an element substrate comprising a micro-element on a top surface of the element substrate;
providing a circuit substrate around the element substrate; and
forming an element housing above the element substrate and the circuit substrate, and the element housing comprising a connecting section which electrically connects the micro-element and the circuit substrate.

21. The method of claim 20, wherein an electrode pad is provided on the element substrate to be electrically connected to the micro-element, and the element housing is provided above the element substrate and the circuit substrate and electrically connects the connecting section and the electrode pad.

22. The method of claim 21, wherein the connecting section comprises a metal pad that is formed on a bottom surface of the element housing, and the metal pad individually connects the neighboring electrode pad and a connection terminal of the circuit substrate.

23. The method of claim 22, wherein the metal pad is electrically connected to the electrode pad and the connection terminal via at least one of a solder ball, a metal bump, a conductive film, and a conductive paste.

24. The method of claim 20, wherein the element substrate is attached to the element housing such that a level of a bottom surface of the element substrate is substantially identical to or higher than a level of a bottom surface of the circuit substrate.

25. The method of claim 20, wherein the micro-element comprises at least one of a micromechanical engineering element, a microelectronics element, and an opto-electronics element.
